(19) United States
(12) Patent Application Publication
(10) Pub. No.: US 2019/0232552 A1
(43) Pub. Date: Aug. 1, 2019

(54) 3D PRINTING METHOD AND PRODUCT

(71) Applicant: SIGNIFY HOLDING B.V., Eindhoven (NL)

(72) Inventors: Marc Andre DE SAMBER, EINDHOVEN (NL); Boudewijn Ruben DE JONG, EINDHOVEN (NL)

(21) Appl. No.: 16/342,389

(22) PCT Filed: Oct. 17, 2017
(86) PCT No.: PCT/EP2017/076501

§ 371 Date: Apr. 16, 2019

(30) Foreign Application Priority Data
Oct. 24, 2016 (EP) 16195212.2

(51) Int. Cl. B29C 64/106; H05K 1/02; H05K 3/00; H05K 3/28

(52) U.S. Cl. CPC B29C 64/106; H05K 1/0274; H05K 1/029; B33Y 80/00; H05K 3/0005; H05K 3/28; H05K 1/0293

(57) ABSTRACT

The invention provides a 3D printing method and product which makes use of a base module which comprises an electrical circuit, wherein the electrical circuit is incomplete. A 3D printed structure over the module completes the electrical circuit of the base module.

### FIELD OF THE INVENTION

This invention relates to 3D printing.

### BACKGROUND OF THE INVENTION

Digital fabrication is set to transform the nature of global manufacturing.

One aspect of digital fabrication is 3D printing. The most widely used 3D printing process is Fused Deposition Modeling (FDM).

FDM printers use a thermoplastic filament, which is heated to its melting point and then extruded, layer by layer, to create a three dimensional object. FDM printers are relatively fast, low cost and can be used for printing complicated 3D objects.

Such printers may be used for printing various shapes using various polymers. To perform a 3D printing process, the printer is controlled using a print command file generated by computer aided design (CAD) software, and this controls how the filament is processed. The quality of the eventual product depends both on the CAD file used to implement the design and the printing filament used.

The 3D printing process may for example be performed over the top of an electronic module. The printing for example defines the aesthetic appearance of the product and/or it performs additional functions. For example, the module may be an LED module and the 3D printed part is an optical beam shaping or beam steering part. The quality of the eventual product thus depends also on the correct design of the original electronic module.

There is a desire to be able to guarantee product quality, but this may be difficult when the electronic module and printing parts (filament and CAD file) are sourced separately. There is also an issue of management of the rights of the designer of a 3D product. Electronic measures may be used to protect the digital design files for a three dimensional object, but these may be circumvented. Furthermore, for a simple 3D product design, the product shape can easily be reverse engineered to create a 3D printing file which generates the product shape. Copies of a 3D object can then be produced without the required permission.

There is therefore a need for a product design and manufacturing method which reduces the simplicity, and hence the economic benefit, of copying a 3D printed product. The invention relates specifically to products which combine a base module having an electric circuit (which base module may for example be an optical component) and an overlying printed structure.

### SUMMARY OF THE INVENTION

The invention is defined by the claims.

According to examples in accordance with an aspect of the invention, there is provided a method of manufacturing a product, comprising:

providing a base module which comprises electrical component, an external contact pad, and a conductor track connecting the contact pad to the electrical component, wherein the conductor track is part of an electrical circuit of the base module, and wherein the conductor track comprises an interrupt so that the electrical circuit is incomplete;

providing a 3D printing filament arrangement; and

controlling a 3D printer to print a 3D printed structure over the base module using the 3D printing filament arrangement.

In the method according to the invention, the 3D printing filament arrangement includes conducting portions, and these conducting portions complete the electrical circuit of the base module by providing a short across the interrupt.

The method according to the invention further comprises the step of printing over the short to finish the 3D printed structure.

This method provides a functional link between the base module and the printed structure over the top of the base module. The printed structure completes the electrical circuit of the base module. This provides a more complex product design than a fully functional module with an independent printed structure over the top. As a result, it becomes more complex to copy the product design.

The 3D printing filament arrangement may comprise a single filament with conducting and non-conducting regions, or it may comprise multiple filaments. Thus, the “conducting portions” may be part of one filament and other non-conducting portions may be part of another filament. In such a case, a dual head printer with two types of filament may be used.

The electrical circuit of the base module comprises a conductor track with an interrupt, and the printing provides a short across the interrupt.

This provides a simple way to link the module function to the printing. It does not add significant complexity to the module or to the printing process but it renders copying more complicated, in that a conventional module design or a conventional printing process will not be suitable.

The method may further comprise the step of providing a solder resist layer over the electrical circuit, with contact holes at the locations of the ends of the conductor track adjacent the interrupt, to form open pads. This makes it more difficult for the interrupt to be corrected by soldering (i.e. a short circuit being introduced), because the interrupt itself is covered in solder resist. The interrupt may be formed as a series of breaks. This makes it more complicated to correct the interrupt manually as there are then multiple short circuit bridges that need to be made.

The method comprises the step of printing over (i.e. on top of) the short to finish the 3D printed structure. In this way, if the short has been made manually in an attempt to circumvent the copy protection measures, for example by soldering, wire bonding, welding, or conductive gluing, the printing process may not then function because the underlying substrate profile has changed.

The electrical circuit of the base module may comprise a first conductor track with an interrupt and a second conductor track within the interrupt, wherein the printing provides a dielectric layer over the second conductor track and a short across the interrupt over the dielectric layer.

This requires a two-stage printing process to correct the interrupt (i.e. provide the required electrical connection), rendering the product more difficult to copy.

The method may comprise forming a connector track, wherein the base module is provided over the connector track, and wherein the printing provides a connection of the conductor track at each side of the interrupt down to the connector track.

In this way, the connection is beneath the module and the printing provides electrical connections at the edge of the module.

The method may for example be used to form an LED lighting unit comprising an LED module and an optical component, wherein the base module is the LED module, and wherein the printing provides the optical component over the LED module.

Examples in accordance with another aspect of the invention provide a product, comprising:

a base module which comprises an electrical component, an external contact pad, and a conductor track connecting the contact pad to the electrical component, wherein the conductor track is part of an electrical circuit of the base module, and wherein the conductor track comprises an interrupt; and

a 3D printed structure over the base module, wherein conducting portions of the 3D printed structure provide a short across the interrupt to complete the electrical circuit of the base module.

This product has electrical functionality which is defined by the combination of the base module and the printed structure over the top.

The electrical circuit of the base module comprises a conductor track with an interrupt, and the printed structure provides a short across the interrupt. This provides an easy way to complete the electrical functionality but which makes copying a more complicated task.

A solder resist layer may be provided over the electrical circuit, with contact holes at the ends of the conductor track adjacent the interrupt to form open pads. The interrupt for example comprises a chain of breaks in the conductor track and a series of contact holes may then be provided.

By providing a further printed structure over the short, copying of the device is made even more complicated, in that if the short is not provided by printing, the shape of the substrate over which the subsequent printing is performed is no longer correct, and the printing process will then abort.

The electrical circuit of the base module for example comprises a first conductor track with an interrupt and a second conductor track within the interrupt, wherein the printed structure comprises a dielectric layer over the second conductor track and a short across the interrupt over the dielectric layer.

The product may have a connector track, wherein the base module is provided over the connector track, and wherein the printed structure comprises a connection of the conductor track at each side of the interrupt down to the connector track.

The product is for example an LED lighting unit comprising an LED module and an optical component, wherein the base module is the LED module, and wherein the 3D printed structure comprises the optical component. The LED lighting unit may be a fully functional luminaire.

The optical component may be a refractive or reflective component, or indeed any type of beam shaping or redirecting (such as beam collimating or beam scattering) optical component.

### BRIEF DESCRIPTION OF THE DRAWINGS

Examples of the invention will now be described in detail with reference to the accompanying drawings, in which:

FIG. 1 shows a fused deposition modeling printer;

FIG. 2 shows a first example of a base module and printed structure to complicate efforts to copy the design;

FIG. 3 shows difficulties which arise if trying to provide copying;

FIG. 4 shows a second example of a base module and printed structure to complicate efforts to copy the design;

FIG. 5 shows a third example of a base module and printed structure to complicate efforts to copy the design;

FIG. 6 shows a method of manufacturing a product; and

FIG. 7 shows a product having a base module and a 3D printed structure over the top.

### DETAILED DESCRIPTION OF THE EMBODIMENTS

The invention provides a 3D printing method and product which makes use of a base module which comprises an electrical circuit, wherein the electrical circuit is incomplete in the base module design. A 3D printed structure over the base module completes the electrical circuit of the base module. This provides an overall device design and manufacturing method which is more difficult to copy.

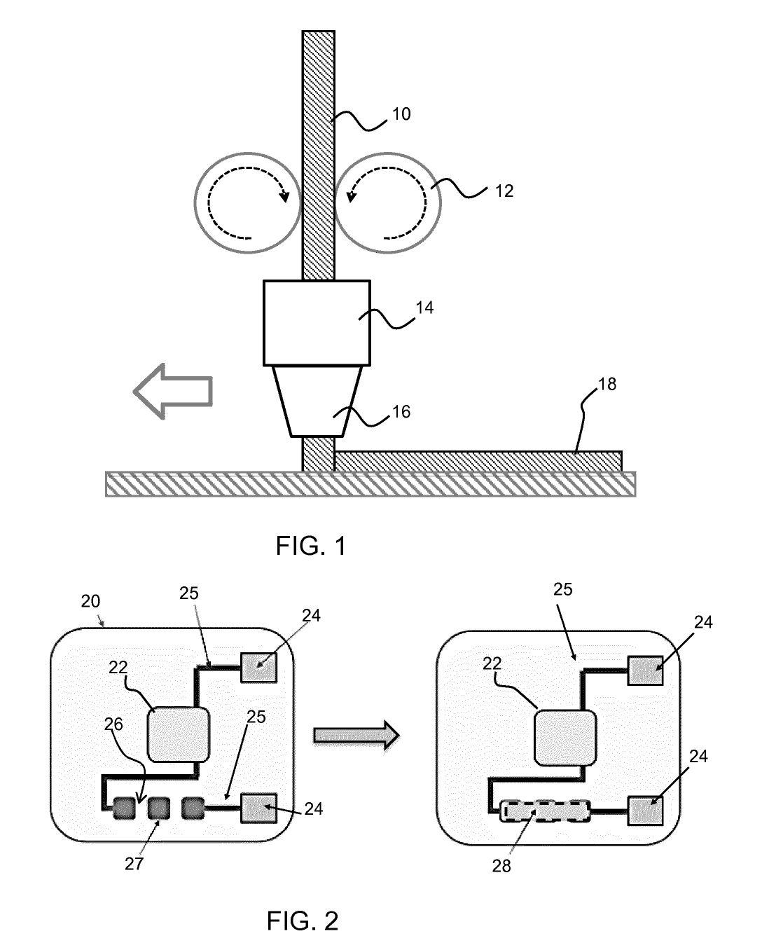

FIG. 1 is used to explain the operation of a fused deposition modeling printer.

A filament 10 is passed between a pair of driver wheels 12 to a printer head 14 having an output nozzle 16. A layer 18 of the material is deposited while in a high viscosity liquid state, which then cools and cures. A 3D structure is built up as a sequence of layer patterns.

The invention relates to product designs that have an electronic base mode and a printed structure over the top. It provides a functional link between the base module, for example an LED engine, and the printed structure, which is defined by the CAD print file (and filament design). By making the combination of the specific base module design and CAD print file a prerequisite to be able to print the final envisioned product properly, copying is made more difficult. An end-user is required to purchase both a CAD file and the matching LED module. The aim of the design is to make the complexity of counterfeiting less worthwhile given a low cost of the end product.

The invention will be described with reference to an LED module, but the concepts can be applied to any product.

FIG. 2 shows a first example of a base module and the way the printing completes the electrical functionality of the base module.

The image on the left shows the base LED module 20. The base module 20 comprises an LED element 22 and external contact pads 24. Conductive tracks 25 connect the contact pads 24 to the LED element 22. The conductive tracks are part of an electrical circuit of the base module. However, the circuit is incomplete, by which is meant there are missing connections to make the circuit functional. In the example shown, there are three breaks 26 in one of the conductive tracks 25. These three breaks together define what will be termed an interrupt, i.e. an open circuit region.

Each part of the conductive track ends at a break 26 with an enlarged track portion forming a conducting pad. The electrical circuit substrate is covered with a solder resist layer, but there is an opening at the enlarged conducting pad, thereby defining open pads 27. The solder resist layer thus has contact holes at the locations of the ends of the conductor track adjacent the break.

The solder resist layer is also open at locations where the LED element and other electrical components are mounted, and where there are other pads that need to be connected to the rest of the product, for example to the driver cabling.

The 3D printer is controlled to print using a 3D printing filament arrangement. Conducting portions of the 3D printing filament, or else a separate conducting filament, complete the electrical circuit of the base module 20. In particular, a conducting ribbon 28 is printed to create short circuits at the breaks 26.

This method provides a functional electrical link between the 3D printing process and the underlying module.

The printing process needs to use a conducting filament at the correct location/time. Thus, the overall product cannot be copied by using a more basic printing process to complete the module. This renders copying more challenging.

For example, it will be explained what will happen if it is attempted to create a short circuit with solder before completing the product with a more basic printing process. An elongate solder deposit (paste) can be applied, but during the melting process, for making a solder connection, the solder will wet the metal open pads 27 and will not form a ribbon of solder, because the solder resist (between the open pads 27) is non-wettable. In this case, the attempted copying would result in three solder balls, one on each of the three open pads 27.

Wire bonding to short circuit the breaks will also not work, as the wire bond has a loop. Because it is not flat, it is therefore not compatible with post-printing on top of that short circuit area.

The arrangement of open pads 27 is thus generally at the location of the interrupt, with the contact pads 27 separated by the breaks 26 in the conductive track. The breaks 26 in this particular example are covered in solder resist.

In this example, the interrupt is in one of the main power supply lines from an external contact, but any other open circuit may be used which renders the circuit non-functional.

This design means the printing process has a required step of printing a conductive track onto (or nearby) the LED module such that an existing conductor track of the module is corrected so as to allow powering, or more generally correct operation, of the LED.

This method is of particular interest for product manufacturing that relies on dual-filament printing, so for product designs that already require printed conductors.

The printing method should be difficult enough that it would not be obvious how to circumvent the copy protection feature, for example by not allowing the user simply to add a solder wire to manually correct the interrupt.

The use of a daisy chain configuration of contact holes as shown in FIG. 2 is a first option which renders this circumvention more difficult.

By providing a number of contact holes, across which conductive material is to be printed, counterfeiting with wire soldering is made much more complicated as explained above.

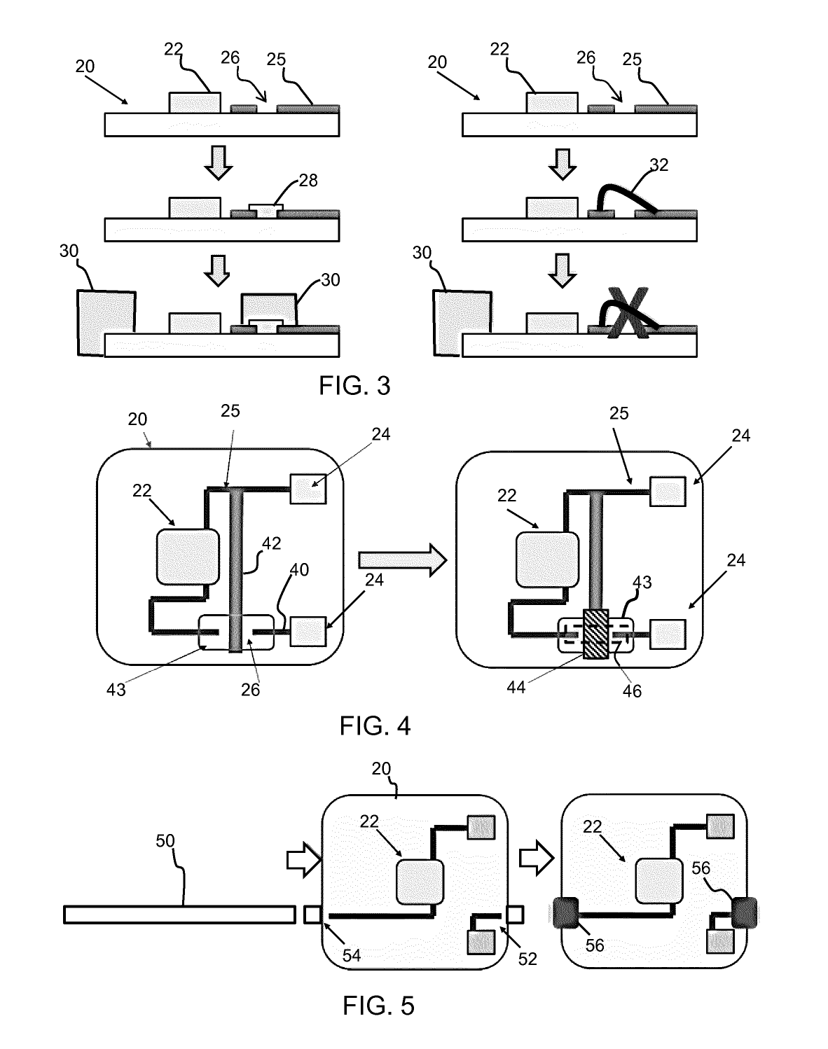

As explained above, although a counterfeiter might try to circumvent the open circuit by soldering wires, such action may be in vain if the subsequent material printing process steps become impossible because of non-flatness/non-planarity of the solder wire addition. This issue is explained with reference to FIG. 3.

The left images show the correct process flow, starting with the base module 20 with the interrupt in the form of a single break 26 in a conducting track 25.

The short circuit 28 is created in the next step following which an insulating printed body 30 is formed. This body 30 has a part over the shorted interrupt.

The right images show the process flow in which it is attempted to cheat. The process flow starts with the base module 20 with the interrupt 26 in a conducting track 25. A wire bond 32 is then provided to restore functionality of the base module. However, the last step shows that this means the subsequent printing fails.

In this design, the subsequent over-printing over the short is made to be a key part of the printing process and the product design.

It is desirable to make the short circuit function performed by the printed structure hidden, for example obscured by a next print layer, so that it is not obvious from the complete end product that there is a requirement to print conductive shorts in order to create a product from that particular module design. For this purpose, the subsequent printing is preferably on top of the short circuited region, i.e. over the location of the previous break 26, so as to make counterfeiting more difficult.

FIG. 4 shows a method based on a dual printing function.

The base module 20 comprises a first conductor track 40 with an interrupt 43 (i.e. the break 26) and a second conductor track 42 which has a portion which extends within the interrupt. This portions lies between the ends of the first conductor track at each side of the break.

If the break 26 is simply shorted, there is then a likely contact to the second conductor track 42 which renders the device non-functional, in this example short circuiting the external contact pads.

To correct the interrupt, the printing provides a dielectric layer 44 over the second conductor track and a short 46 (shown dotted) across the break over the dielectric layer.

This means the printing is even more difficult to copy, in that it requires dielectric and conducting parts to complete the circuit of the underlying module.

Keeping these functional features flat means the surface remains compatible with the next steps in the printing process. Counterfeiting disturbs these next printing steps as well by changing the profile of the substrate. Counterfeiting is thus made more difficult to circumvent as two printing materials and a more complex printing method are used.

FIG. 5 shows another example.

The process starts by forming a connector track 50 on a substrate. The track is for example formed on a base part of the luminaire. This base part could be an input part for the 3D printing process, or it might be the result of a preceding sequence of the 3D printing process.

The connector track 50 extends the full width of the base module 20 and projects laterally beyond two edges. They do not need to be opposing edges, and they may even be on the same edge, in which case the connector track may have a U-shape.

The base module 20 is then provided over the connector track as part of the base module assembly, as shown in the middle image.

The base module again has an interrupt, but the required connection is from one side of the module—the conductor track end 52—to the another side of the module—the conductor track end 54. The interrupt may thus be considered to extend across the full width of the module in this example. It may instead be considered to extend between any two points around the periphery of the module. The two points may even be adjacent each other at the same side of the module.

The printing provides a connection 56 of the conductor track down to the connector track at each side of the interrupt.

In this way, the connector 50 is beneath the module and the printing provides electrical connections at one or more edges of the module. The short circuiting pathway is thus hidden under the LED module.

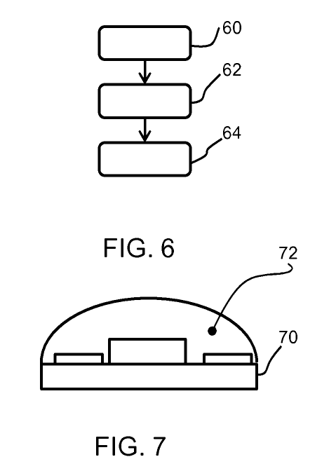

FIG. 6 shows a manufacturing method.

In step 60, a base module is provided which comprises an electrical circuit, wherein the electrical circuit is incomplete.

In step 62, a 3D printing filament arrangement is provided including conducting portions.

In step 64, a 3D printer is controlled to print using the 3D printing filament, wherein the conducting portions of the 3D printing filament arrangement complete the electrical circuit of the base module.

Note that the printed structure may provide additional electrical functionality in addition to completing the circuit of the base module. Thus, the base module circuit is completed in the sense that the circuit function of the base module is rendered operational. Additional circuit functions may be added by the printed structure.

FIG. 7 shows a lighting module comprising a base module 70 in the form of an LED engine and a printed structure 72 which provides beam shaping or collimation of the light output from the LED engine. This provides a low cost 3D printed integrated light module. The printed structure in this example is a refractive lens. The printed structure may instead be a reflective optical component.

The invention is of interest more generally to any 3D printed objects and products which includes an electrical circuit. The invention is of primary interest for low-price entry products, for example home-printed products.

The examples above show a single LED module. However, multiple LED modules (or indeed other types of electrical module) may be formed by a single manufacturing process. The LED modules may be formed with other electrical elements, that are enabled in their overall functionality using the same approach as explained above. Different modules may be electrically connected to each other, or some or all may be individually enabled by the 3D printing process as explained above. These other electrical elements may for example be driver modules and/or sensors and/or actuators.

Other variations to the disclosed embodiments can be understood and effected by those skilled in the art in practicing the claimed invention, from a study of the drawings, the disclosure, and the appended claims. In the claims, the word “comprising” does not exclude other elements or steps, and the indefinite article “a” or “an” does not exclude a plurality. The mere fact that certain measures are recited in mutually different dependent claims does not indicate that a combination of these measured cannot be used to advantage. Any reference signs in the claims should not be construed as limiting the scope.

1. A method of manufacturing LED lighting unit comprising an LED module and an optical component, wherein the method comprises the steps of:
providing the LED module;
providing a 3D printing filament arrangement; and
controlling a 3D printer to print a 3D printed structure over the LED module using the 3D printing filament arrangement, the 3D printed structure comprising the optical component,
wherein the LED module has an electrical circuit comprising an LED element, an external contact pad, and a conductor track connecting, the contact pad to the LED element, the conductor track comprising an interrupt so that the electrical circuit of the LED module is complete;
wherein the 3D printing filament arrangement includes conducting portions,
wherein the conducting portions complete the electrical circuit of the LED module by providing a short across the interrupt, and
wherein the method further comprises the step of:
printing over the short to finish the 3D printed structure.

2. A method as claimed in claim 1, further comprising the step of providing a solder resist layer over the electrical circuit, with contact holes at the locations of the ends of the conductor track adjacent the interrupt, to form open pads.

3. A method as claimed in claim 1, wherein the interrupt is an interrupt in a first conductor track, wherein a second conductor track is present within the interrupt, and wherein the printing provides a dielectric layer over the second conductor track.

4. A method as claimed in claim 1, further comprising the step of forming a connector track, wherein the LED module is provided over the connector track, and wherein the printing provides a connection of the conductor track at each side of the interrupt down to the connector track.

5. (canceled)

6. An LED lighting unit, comprising:
an LED module; and
an optical component over the LED module,
wherein the LED module comprises an LED element, an external contact pad, and a conductor track connecting the contact pad to the LED element, the conductor track being part of an electrical circuit of the LED module and comprising an interrupt;
wherein the optical component is comprised in a 3D printed structure, and
wherein conducting portions of the 3D printed structure provide a short across the interrupt to complete the electrical circuit of the LED module.

7. A product as claimed in claim 6, further comprising a solder resist layer over the electrical circuit, wherein the solder resist layer comprises contact holes at the ends of the conductor track adjacent the interrupt to form open pads.

8. A product as claimed in claim 6, wherein the interrupt comprises a chain of breaks in the conductor track.

9. A product as claimed in claim 6, wherein the interrupt is an interrupt in a first conductor track, wherein a second conductor track is present within the interrupt, and wherein the 3D printed structure comprises a dielectric layer over the second conductor track.

10. A product as claimed in claim 6, further comprising a connector track, wherein the LED module is provided over the connector track, and wherein the 3D printed structure comprises a connection of the conductor track at each side of the interrupt down to the connector track.

11. (canceled)
